(19) United States
(12) Patent Application Publication
(10) Pub. No.: US 2023/0353140 A1
(43) Pub. Date: Nov. 2, 2023

(54) BIASING BODY NODE OF A TRANSISTOR

(71) Applicants: Shaoxing Yuanfang Semiconductor Co., Ltd., Shaoxin (CN); Spirit Semiconductor Limited, Reading (GB)

(72) Inventors: Sebastian Diebold, Pangbourne (GB); Georgios Bilionis, Reading (GB)

(21) Appl. No.: 17/663,234

(22) Filed: May 13, 2022

Related U.S. Application Data
(60) Provisional application No. 63/363,815, filed on Apr. 29, 2022.

(51) Int. Cl. H03K 17/56; H04B 1/44

(52) U.S. Cl. CPC H03K 17/56; H04B 1/44

(57) ABSTRACT

A semiconductor circuit provided according to an aspect of the present disclosure contains a component having an impedance coupled between the body node and the gate node of a first transistor, wherein a magnitude of the impedance is determined by a voltage between the drain node and the source node of the first transistor. In an embodiment, the component comprises a second transistor, a first resistor and a second resistor connected in series across the drain node and the source node of the first transistor, with the first resistor and the second resistor being connected at a first junction. A gate node of the second transistor is coupled to the first junction, a source node of the second transistor is coupled to the body node, and a drain node of the second transistor is coupled to the gate node of the first transistor.

### PRIORITY CLAIM

The present patent application is related to and claims the benefit of priority to the co-pending US provisional patent application entitled, “Body Node Biasing in RF Switches”, Ser. No. 63/363,815, Attorney Docket Number: AURA-034-USPR, Filed: 29 Apr. 2022, which is incorporated in its entirety herewith to the extent not inconsistent with the description herein.

### BACKGROUND

### Technical Field

Embodiments of the present disclosure relate generally to transistors having body nodes, and more specifically to biasing of such body nodes.

### Related Art

A transistor refers to a component built using semiconductor material with three principal terminals. The current passing between two of these terminals is controlled by either a voltage or current presented on the third or control terminal, as is well known in the relevant arts.

A body node as a fourth node, is present on some type of transistors, such as those fabricated using SOI (Silicon on Insulator) technology.

It is desirable that the body node be appropriately biased for obtaining superior performance characteristics in usage of the corresponding transistor. For example, transistors may exhibit one or more of less linearity, longer switching times, etc., when the body node is not appropriately biased, as is also well known in the relevant arts.

Aspects of the present disclosure are directed to biasing body nodes of such transistors.

### BRIEF DESCRIPTION OF THE VIEWS OF DRAWINGS

Example embodiments of the present disclosure will be described with reference to the accompanying drawings briefly described below.

FIG. 1 is a representation of a transistor having a body node.

FIG. 2 is a circuit diagram illustrating the manner in which a body node of a transistor is biased in an embodiment.

FIGS. 3A-3H are plots of curves representing a comparison of several performance parameters of an RF switch with, and without, body biasing according to aspects of the present disclosure.

FIG. 4 is a circuit diagram of a switch stack in an embodiment of the present disclosure.

FIG. 5 is a circuit diagram of an SPDT switch in an embodiment of the present disclosure.

FIG. 6 is a block diagram showing the implementation details of an example device/system in an embodiment of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

A semiconductor circuit provided according to an aspect of the present disclosure contains a component having an impedance coupled between the body node and the gate node of a first transistor, wherein a magnitude of the impedance is determined by a voltage between the drain node and the source node of the first transistor.

In an embodiment, the component comprises a second transistor, a first resistor and a second resistor connected in series across the drain node and the source node of the first transistor, with the first resistor and the second resistor being connected at a first junction. A gate node of the second transistor is coupled to the first junction, a source node of the second transistor is coupled to the body node, and a drain node of the second transistor is coupled to the gate node of the first transistor.

It is observed that such a configuration leads to several improvements in performance characteristics of the first transistor when used as a RF switch.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Transistor with a Body Node

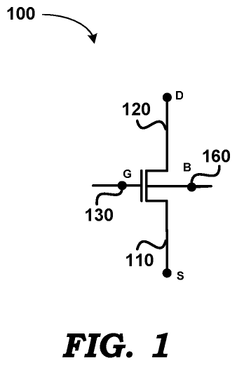

FIG. 1 is a representation of a transistor having a body node. Transistor 100 is shown having source 110, drain node 120, gate node 130 and body node 160, operable as noted briefly in the background section above. As also noted there, it is desirable to appropriately bias body node 160. The manner in which transistor 100 can be biased in an embodiment is described below in further detail.

### 3. Biasing the Body Node

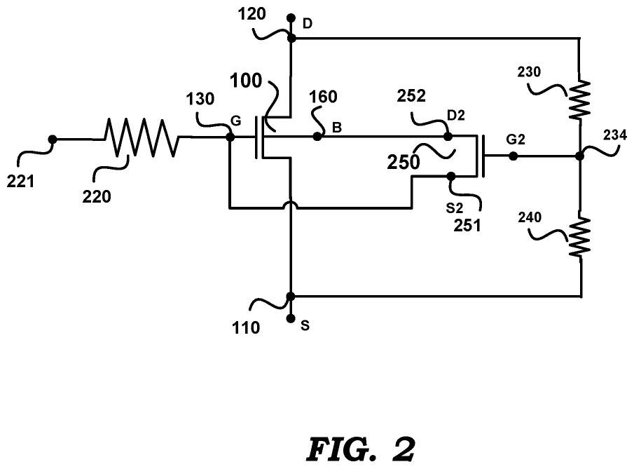

FIG. 2 is a circuit diagram illustrating the manner in which a body node of a transistor is biased in an embodiment. Semiconductor circuit 200 is shown containing transistor 100 along with transistor 250, and resistors 220, 230, and 240.

Resistors 230 and 240 are shown connected in series at junction 234. The series of transistors is shown connected between drain node 120 and source node 110 of transistor 100. The voltage between gate node 234 and source node 251 changes when the voltage at node 130 changes. The gate terminal of transistor 250 is connected to junction 234. The source node 251 and drain node 252 are respectively connected to body node 160 and gate node 130 of transistor 100. Control voltage is applied at node 221 to gate node 130 via resistor 220 to switch transistor 100 ON or OFF, in a known way. In general, node 130 is at logic high if the transistor 100 is on (conducting) and at logic low if the transistor is off (blocking).

It may thus be observed that the resistance offered by transistor 250 between its source node 251 and drain node 252 is determined by the voltage at junction 234, in addition to the voltages at nodes 130 and 160. The offered resistance is also between body node 160 and gate node 130 of transistor 100. Therefore, the voltage across the source node 110 and drain node 120 of transistor 100, along with the operational characteristics of transistor 250, determines the impedance between body node 160 and gate node 130.

In the steady state, voltages at node 120 and 110 are substantially equal. During switching, the voltages at nodes 110, 120, and 130 all change. Specifically, the voltage across gate node 234 (G2) and source node 251 (S2), and thus the impedance presented by transistor 250, is a function of voltages at nodes 110, 120, and 130. During RF operation (especially with DC/bias voltages or large magnitude signals that extend to or beyond the linear region of the transfer characteristics of transistor 100), the same as noted generally above applies as during switching.

The gate-length, gate-width, and the number of fingers (when fabricated with multiple fingers) of transistor 250, and the resistor values of resistors 230 and 240 may be chosen appropriately to achieve the required small-signal and large-signal steady state performance, as well as transient switching performance, of transistor 100.

The combination of transistor 250 and resistors 230/240 represent an example component which offers resistance determined by the voltage between the drain and source nodes of transistor 100. The arrangement has been found to improve several operating parameters of transistor 100, as described briefly below.

### 4. Improved Performance Characteristics

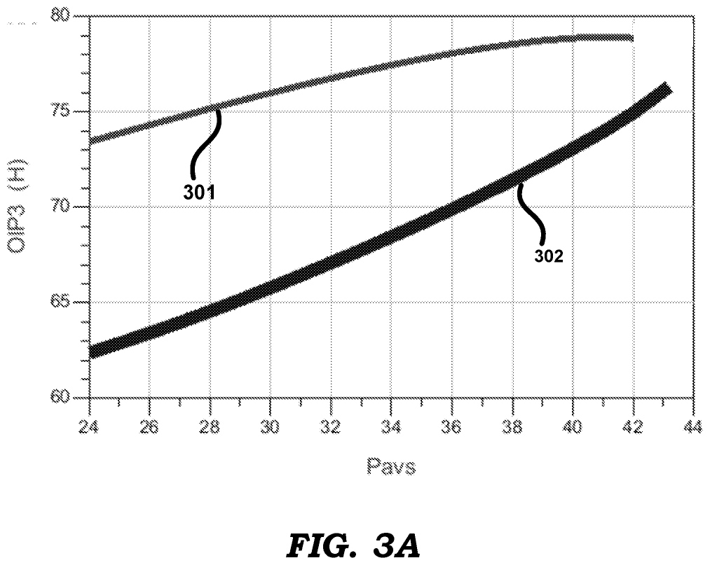

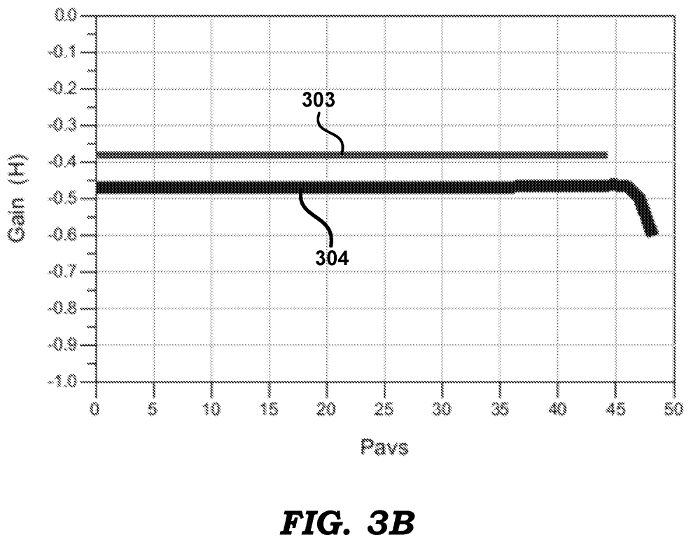

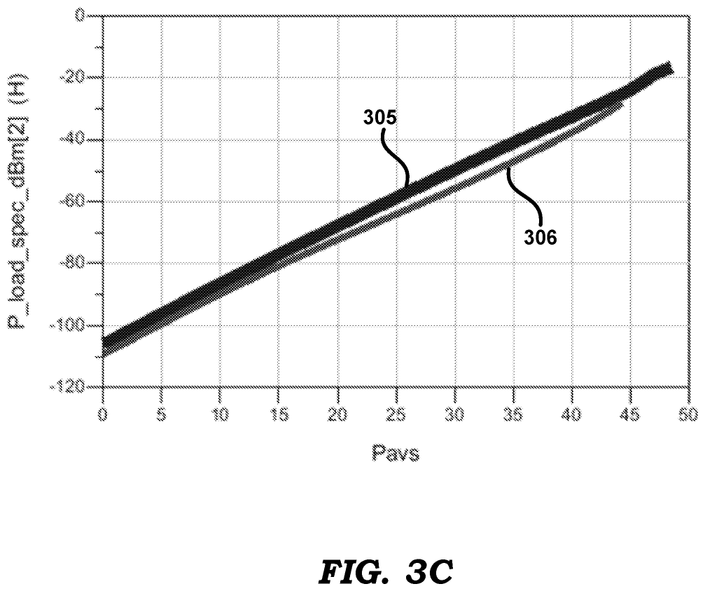

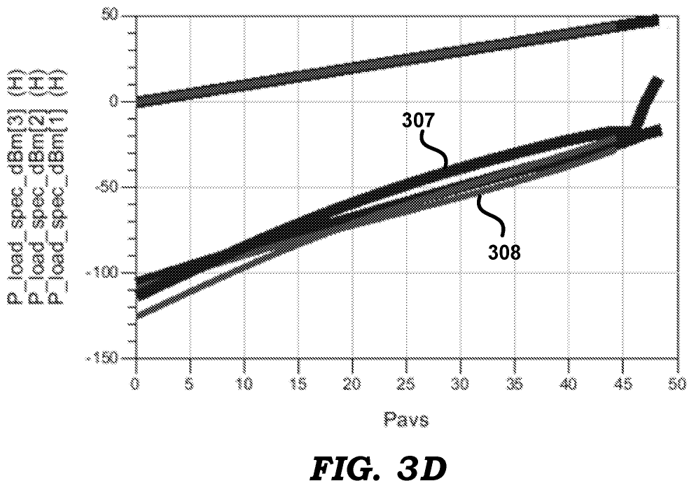

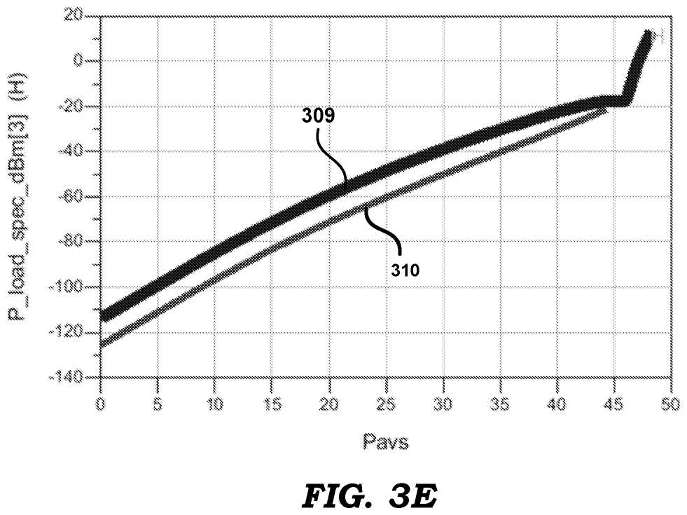

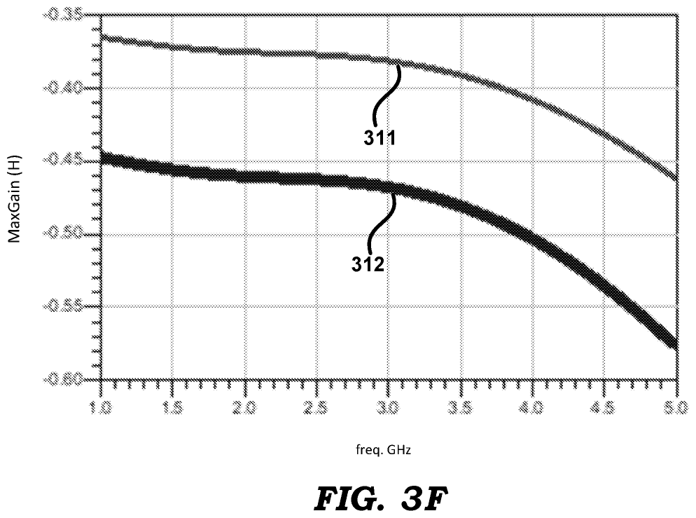

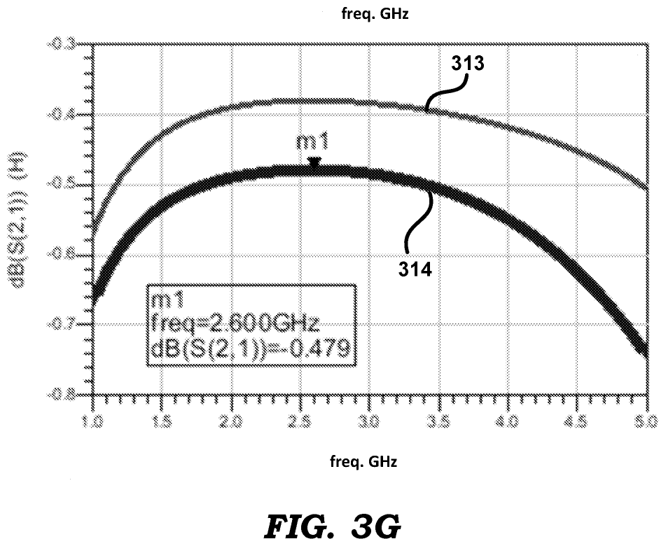

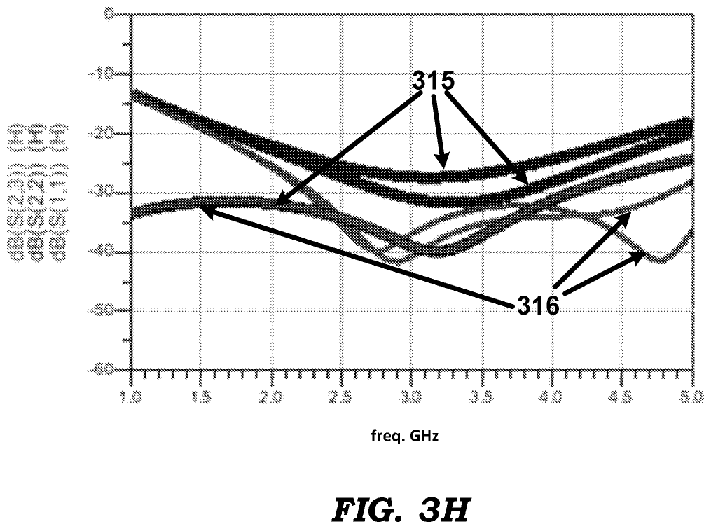

FIGS. 3A-3H are plots of curves representing corresponding parameters of semiconductor circuit 200 when used as an RF switch.

FIG. 3A shows two curves 301 and 302 respectively showing the OIP3 (output 3^{rd} order intercept point) versus input power with and without the body biasing according to the present disclosure. It may be observed that the OIP3 is better when body biasing according to the present disclosure is employed.

FIG. 3B shows two curves 303 and 304 respectively showing the insertion loss versus input power with and without the body biasing according to the present disclosure. It may be observed that the insertion loss is smaller when body biasing according to the present disclosure is employed.

FIG. 3C shows two curves 306 and 305 respectively showing the second harmonic versus input power with and without the body biasing according to the present disclosure. It may be observed that the second harmonic values are smaller when body biasing according to the present disclosure is employed.

FIG. 3D shows two curves 308 and 307 respectively showing second harmonic and third harmonic in dBm versus input power with and without the body biasing according to the present disclosure. It may be observed that the values on curve 308 are smaller.

FIG. 3E shows two curves 310 and 309 respectively showing the third harmonic versus input power with and without the body biasing according to the present disclosure. It may be observed that the third harmonic values are smaller when body biasing according to the present disclosure is employed.

FIG. 3F shows two curves 311 and 312 respectively showing insertion loss (that can be achieved with perfect input and output impedance matching) versus frequency with and without the body biasing according to the present disclosure. It may be observed that the insertion loss values are smaller when body biasing according to the present disclosure is employed.

FIG. 3G shows two curves 313 and 314 respectively showing insertion loss versus frequency with and without the body biasing according to the present disclosure. It may be observed that the insertion loss is smaller when body biasing according to the present disclosure is employed.

FIG. 3H shows two sets of curves 316 and 315, with each set showing three parameters (namely reflection-loss at the input and output ports, and isolation values) versus frequency with and without the body biasing according to the present disclosure.

It may be observed that body-node biasing according to the present disclosure provides improved performance.

### 5. Deployment Example

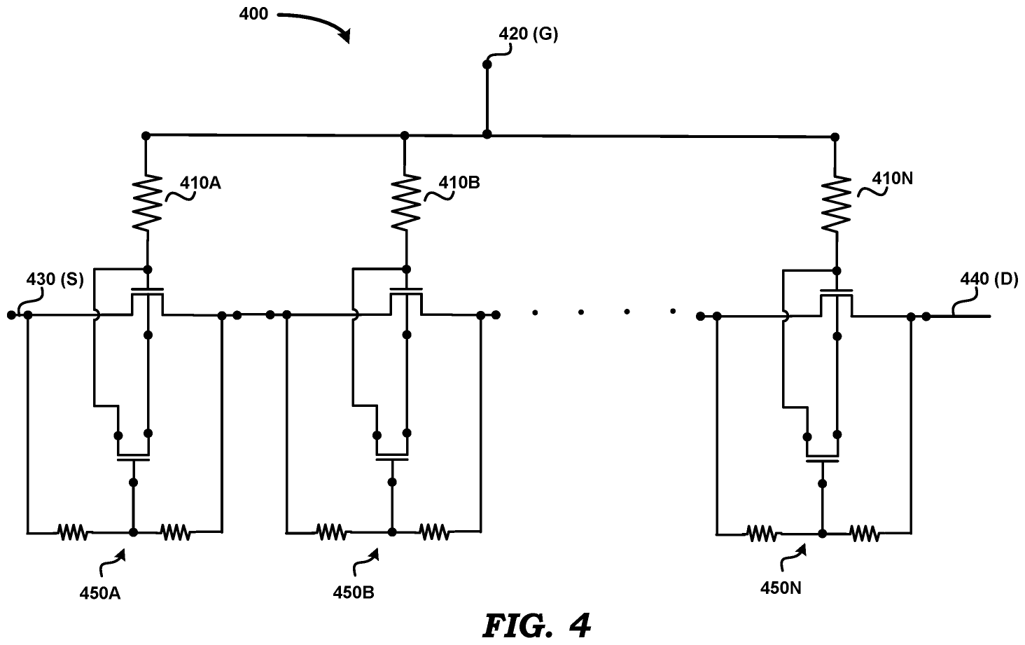

FIG. 4 is a diagram showing a series connection of multiple switches, with each switch implemented as semiconductor circuit 200 described above, to form a switch stack. In FIG. 4, switch stack 400 is shown with switches 450A through 450N. Terminals 420, 430 and 440 respectively represent the gate, source and drain terminals of the switch stack. Such stacking may be used when higher power levels or voltages need to be supported by an RF switch.

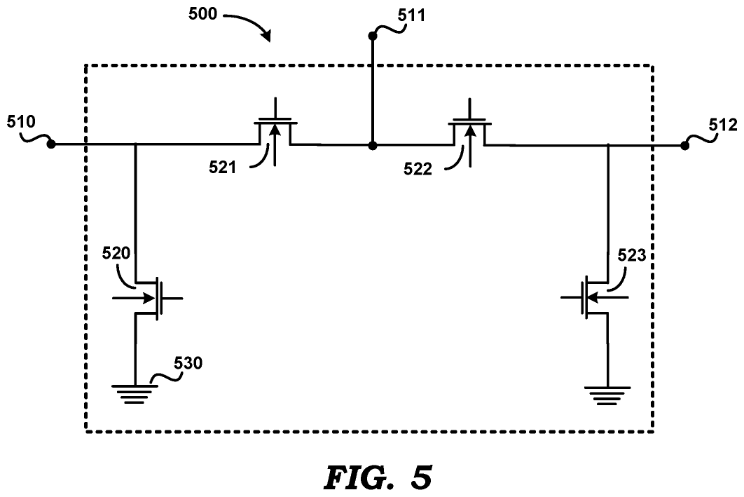

FIG. 5 is a diagram showing an SPDT (single pole, double throw) switch 500 built using multiple ones of switch (semiconductor circuit) 200. SPDT switch 500 is used to connect terminal 511 (pole) to either terminal 510 (throw 1) or terminal 512 (throw2). Each of switches 520-523 may represent one switch (such as switch 200) or a stack of switches (such as stack 400). Switch 521 is in the path between terminals 511 and 510. Switch 520 is present in a shunt arm between terminals 510 and ground (530/constant reference potential). Similarly, switch 522 is in the path between terminals 511 and 512. Switch 523 is present in a shunt arm between terminals 512 and ground. When SPDT switch 500 is to connect terminal 510 to terminal 511, switches 521 and 523 are switched ON, while switches 520 and 522 are switched OFF. When SPDT switch 500 is to connect terminal 512 to terminal 511, switches 521 and 523 are switched OFF, while switches 522 and 520 are switched ON.

It should be appreciated that SPDT is merely an example component in which the features of the invention can be implemented. However, aspects of the present disclosure can be implemented in other components/devices such as SPSTs (single pole single throw), SPxTs (single pole and X number of throws), where x=1 . . . n (integer), as will be apparent to a skilled practitioner by reading the disclosure provided herein.

An RF switch implemented as described above can be used in a device or system as described briefly next.

### 6. Device/System

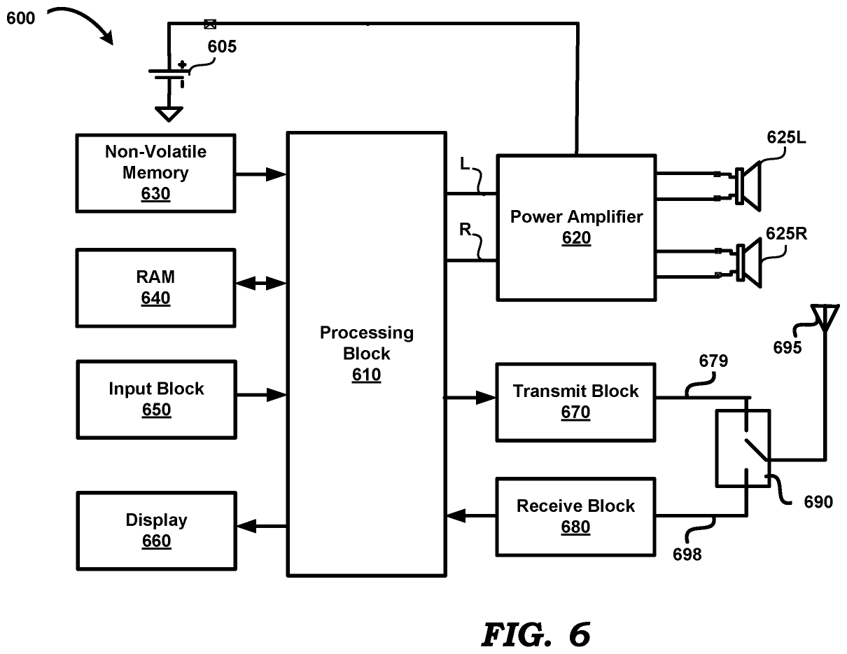

FIG. 6 is a block diagram showing the implementation details of an example device/system in an embodiment of the present disclosure. Mobile phone 600 is shown containing battery 605, processing block 610, power amplifier 620, speakers 625L and 625R, non-volatile memory 630, random access memory (RAM) 640, input block 650, display 660, transmit block 670, receive block 680, switch 690 and antenna 695. The specific components/blocks of mobile phone 600 are shown merely by way of illustration. However, mobile phone 600 may contain more or fewer components/blocks.

Battery 605 represents an unregulated power supply, used to power the various blocks of mobile phone 600. Although not indicated, one or more of blocks other than power amplifier 620 may receive power for operation from battery 605 via corresponding regulated power supplies (not shown, but which could be, for example, implemented as linear regulators).

In FIG. 6, the signals on paths L and R are assumed to be digital signals representing the left and right audio channels of an audio system. Power amplifier 620 generates corresponding power-amplified outputs to drive respective speakers 625L and 625R. Although power amplifier 620 is noted as receiving input signals from processing block 610 in digital form, in another embodiment power amplifier 620 receives input signals from processing block 610 in analog form, the digital to analog conversion of the corresponding digital signals being performed within a digital to analog converter within processing block.

Processing block 610 may store speech and/or audio signals that are represented by the signal provided as input (whether in analog from or digital form) to power amplifier 620 on paths L and R in the form of files in non-volatile memory 630. Such files may be input to mobile phone 600 via input block 650 or received via receive block 680 and antenna 695.

Input block 650 represents one or more input devices used to provide user inputs to mobile phone 600. Input block 650 may include a keypad, microphone, etc. Display 660 represents a display screen (e.g., liquid crystal display) to display images generated by processor 610.

Antenna 695 operates to receive from and transmit to a wireless medium, corresponding wireless signals carrying speech and/or audio. Switch 690 represents an SPDT switch, and may be controlled by processing block 610 (connection not shown) to connect antenna 695 either to receive block 680 via path 698, or to transmit block 670 via path 679, depending on whether mobile phone 600 is to receive or transmit wireless signals. Switch 690 can be implemented as SPDT switch 500 as described in detail above.

Transmit block 670 receives data/speech/audio (information signal in general) to be transmitted from processing block 610, generates a radio frequency (RF) signal modulated by the information signal according to corresponding standards such as GSM, CDMA, etc., and transmits the RF signal via switch 690 and antenna 695. Receive block 680 receives an RF signal bearing an information signal via switch 690, path 698 and antenna 695, demodulates the RF signal, and provides the extracted information (speech/audio/data) to processing block 610.

Non-volatile memory 630 is a non-transitory machine readable medium, and stores instructions, which when executed by processing block 610, causes mobile phone 600 to provide several features. RAM 630 is a volatile random access memory, and may be used for storing instructions and data.

### 7. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 2, 4, 5 and 6, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

In the instant application, the power and ground terminals are referred to as constant reference potentials.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. A semiconductor circuit comprising:
a first transistor having a source node, a drain node, a gate node and a body node; and
a component having an impedance coupled between said body node and said gate node, wherein a magnitude of said impedance is determined by a voltage between said drain node and said source node.

2. The semiconductor circuit of claim 1, wherein said component comprises a second transistor.

3. The semiconductor circuit of claim 2, said component further comprises:
a first resistor and a second resistor connected in series across said drain node and said source node of said first transistor, wherein said first resistor and said second resistor are connected at a first junction,
wherein a gate node of said second transistor is coupled to said first junction, a source node of said second transistor is coupled to said body node, a drain node of said second transistor is coupled to said gate node of said first transistor.

4. The semiconductor circuit of claim 3, wherein said first transistor, said second transistor, said first resistor and said second resistor are fabricated on a single wafer using SOI (Silicon on Insulator) technology.

5. The semiconductor circuit of claim 1, wherein said first transistor and said component together operate as a Radio Frequency (RF) switch.

6. A system comprising:
a transmitter to generate a radio frequency (RF) signal;
a receiver to process another RF signal;
an antenna to transmit, on a wireless medium, said RF signal received from said transmitter, said antenna to receive said another RF signal on said wireless medium and to forward said another RF signal to said receiver; and
a single pole double throw (SPDT) switch having a pole terminal coupled to said antenna, a first throw terminal coupled to said transmitter, and a second throw terminal coupled to said receiver, said SPDT switch to couple said transmitter to said antenna during a transmit duration, said RF switch to couple said receiver to said antenna during a receive duration, said SPDT switch comprising a plurality of RF switches,
wherein an RF switch of said SPDT switch comprises:
a first transistor having a source node, a drain node, a gate node and a body node; and
a component having an impedance coupled between said body node and said gate node, wherein a magnitude of said impedance is determined by a voltage between said drain node and said source node.

7. The system of claim 6, wherein said component comprises a second transistor.

8. The system of claim 7, wherein said component further comprises:
a first resistor and a second resistor connected in series across said drain node and said source node of said first transistor, wherein said first resistor and said second resistor are connected at a first junction,
wherein a gate node of said second transistor is coupled to said first junction, a source node of said second transistor is coupled to said body node, a drain node of said second transistor is coupled to said gate node of said first transistor.

9. The system of claim 8, wherein said first transistor, said second transistor, said first resistor and said second resistor are fabricated on a single wafer using SOI (Silicon on Insulator) technology.
